(19) United States
(12) Patent Application Publication
(10) Pub. No.: US 2025/0130501 A1
(43) Pub. Date: Apr. 24, 2025

(54) ENHANCED FIELD STITCHING WITH CORRECTIVE CHEMISTRY

(71) Applicant: Geminatio, Inc., Schenectady, NY (US)

(72) Inventors: Brennan Peterson, Longmont, CO (US); Phillip D. Hustad, Longmont, CO (US)

(73) Assignee: Geminatio, Inc., Schenectady, NY (US)

(21) Appl. No.: 18/686,796

(22) PCT Filed: Aug. 25, 2022
(86) PCT No.: PCT/US2022/041567

§ 371 Date: Feb. 26, 2024

Related U.S. Application Data
(60) Provisional application No. 63/236,838, filed on Aug. 25, 2021.

(51) Int. Cl. G03F 7/20; G03F 7/004; G03F 7/038; G03F 7/039; G03F 7/16

(52) U.S. Cl. CPC G03F 7/2022; G03F 7/0045; G03F 7/0048; G03F 7/038; G03F 7/039; G03F 7/168

(57) ABSTRACT

A method of patterning a substrate is described. The method includes the steps of providing a resist layer on the substrate, exposing the resist later to a first pattern of actinic radiation to form a latent imagine in the resist layer, and exposing the resist layer to a second pattern of actinic radiation to form a second latent imagine in the resist later, wherein the first latent image and the second latent image are adjacent. The method further includes developing the resist layer to form a relief patten that includes a first set of trenches corresponding to the first pattern of actinic radiation and a second set of trenches corresponding to the second pattern of actinic radiation, wherein the first set of trenches and the second set of trenches are not contiguous. Next, the method includes coating the relief pattern with a solubility-shifting agent, followed by diffusing the solubility-shifting agent a predetermined distance into the resist layer, wherein the solubility-shifted region of the resist borders the first relied pattern, and lastly developing the resist layer to stitch together the first set of trenches and the second set of trenches.

### BACKGROUND

Microfabrication of semiconductor devices includes various steps such as film deposition, pattern formation, and pattern transfer. Materials and films are deposited on a substrate by spin coating, vapor deposition, and other deposition processes. Pattern formation is typically performed by exposing a photo-sensitive film, known as a photoresist, to a pattern of actinic radiation using a KrF excimer laser at 248 nm, ArF excimer laser at 193 nm, or an extreme ultraviolet (EUV) exposure tool at 13.5 nm, and subsequently developing the photoresist to form a relief pattern. The relief pattern then acts as an etch mask, which, when one or more etching processes are applied to the substrate, cover portions of the substrate that are not to be etched. Line cuts are normally achieved on a substrate using such photolithography steps, where each cut is placed individually with a separate lithography exposure. This is challenging as line widths decrease, especially when cuts are to be placed near each other.

For very large devices, a single field exposure, for example approximately 25×35 mm, may be too small. For example, large image sensors can be 50×50 mm, and can require at least 4 exposures to expose a complete, single die. Between those different exposed regions, the different features are desirably linked, so that there is one “virtual” exposure. Similarly, to making panoramic views in photography, multiple images are overlapped in order to create a final, combined image. While image stitching/combining is largely a pixel analysis, with semiconductor fabrication the stitching is physical. Accordingly, accurate alignment is needed to prevent device failure.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method of patterning a substrate including providing a resist layer on the substrate, exposing the resist layer to a first pattern of actinic radiation to form a first latent image in the resist layer, exposing the resist layer to a second pattern of actinic radiation to form a second latent image in the resist layer, wherein the first latent image and the second latent image are adjacent, and developing the resist layer to form a relief pattern. The relief pattern includes a first set of trenches corresponding to the first pattern of actinic radiation and a second set of trenches corresponding to the second pattern of actinic radiation, wherein the first set of trenches and the second set of trenches are not contiguous. Next the method includes coating the relief pattern with a solubility-shifting agent, diffusing the solubility-shifting agent a predetermined distance into the resist layer, and developing the resist layer to stitch together the first set of trenches and the second set of trenches.

In another aspect, embodiments disclosed herein relate to a method of patterning a substrate including providing a first resist layer on a substrate, exposing the first resist layer to a first pattern of actinic radiation to form a first latent image, exposing the resist layer to a second pattern of actinic radiation, and developing the resist layer to form a relief pattern comprising a first set of trenches corresponding to the first pattern of actinic radiation and a second set of trenches corresponding to the second pattern of actinic radiation, wherein the first set of trenches and the second set of trenches are not contiguous. Next the method includes coating the relief pattern with a solubility-shifting agent, coating the relief pattern with a second resist layer, and diffusing the solubility-shifting agent a predetermined distance into the second resist layer to provide a solubility-shifted region of the second resist, wherein the solubility-shifted region of the second resist borders the first relief pattern. Then, the method includes developing the second resist layer to stitch together a plurality of trenches.

In another aspect, embodiments disclosed herein relate to a method of patterning a substrate including providing a first resist layer on a substrate, exposing the first resist layer to a first pattern of actinic radiation to form a first latent image, exposing the resist layer to a second pattern of actinic radiation, and developing the first resist layer to form a first relief pattern comprising a first set of trenches corresponding to the first pattern of actinic radiation and a second set of trenches corresponding to the second pattern of actinic radiation, wherein the first set of trenches and the second set of trenches are not contiguous. Next the method includes coating the first relief pattern with a solubility-shifting agent, depositing a second resist on the first relief pattern such that the second resist is in contact with the first relief pattern, and diffusing the solubility-shifting agent a predetermined distance into the first resist layer, wherein the solubility-shifted region of the first resist borders the second resist. and developing the second resist layer to stitch together a plurality of trenches.

Other aspects and advantages of the claimed subject matter will be apparent from the following description and the appended claims.

### BRIEF DESCRIPTION OF DRAWINGS

FIG. 1 is a block-flow diagram of a method in accordance with one or more embodiments of the present disclosure.

FIGS. 2A, 2C, 2E, 2G, 2I, 2K, and 2M are cross-sectional schematic illustrations of coated substrates at respective points of a method in accordance with one or more embodiments the present disclosure. FIGS. 2B, 2D, 2F, 2H, 2J, 2L, and 2N are corresponding top view schematic illustrations.

FIG. 3 is a block-flow diagram of another method in accordance with one or more embodiments of the present disclosure.

FIGS. 4A, 4C, 4E, 4G, 4I, 4K, 4M, 4O, 4Q, and 4S are cross-sectional schematic illustrations of coated substrates at respective points of a method in accordance with one or more embodiments the present disclosure. FIGS. 4B, 4D, 4F, 4H, 4J, 4L, 4N, 4P, 4R and 4T are corresponding top view schematic illustrations.

### DETAILED DESCRIPTION

The present disclosure generally relates to methods of patterning a semiconductor substrate. In one or more embodiments, the methods include forming a controlled, narrow cut on a substrate by stitching together trenches.

Herein, the terms “semiconductor substrate” and “substrate” are used interchangeably, and may be any semiconductor material including, but not limited to, semiconductor wafers, semiconductor material layers, and combinations thereof. In the present disclosure, the term “photoresist” may be used to refer to a resist material that comprises a photoacid generate and is patterned using light, whereas the term “resist” may be used to describe a resist material that is not patterned using light. Herein “a coated substrate” refers to a substrate that is coated with one or more layers, such as a first resist layer and a second resist layer. Herein “a latent image” refers to a region in the photoresist that is exposed to light, but not developed.

Unlike conventional lithography patterning, methods disclosed herein achieve multiple cuts from one photolithography step, while conventional processes require multiple photolithography steps. Further, methods may include cutting a narrow line directly onto a substrate.

Conventional die stitching methods match ends, or use large “catch” areas for stitching. But these enlarged catch areas reduce density and valuable space for transistors.

Techniques herein improve overlay for die stitching, enabling critical optoelectronic and semiconductor devices without sacrificing critical performance capabilities. Techniques include using chemical treatments to improve feature registration, applying this to layer-in-layer stitching use cases with multiple exposure enhancement. Such cases enable very large dies to be fabricated, even dies up to a size of a wafer, while maintaining density and performance.

Techniques herein include selective attachment processing, which improves resist formation at the boundary between stitched regions. This substantially reduces the design and overlay burden for stitched features, and eliminates some errors. With this method, stitching can be done without error at sub nanometer precision and at full density.

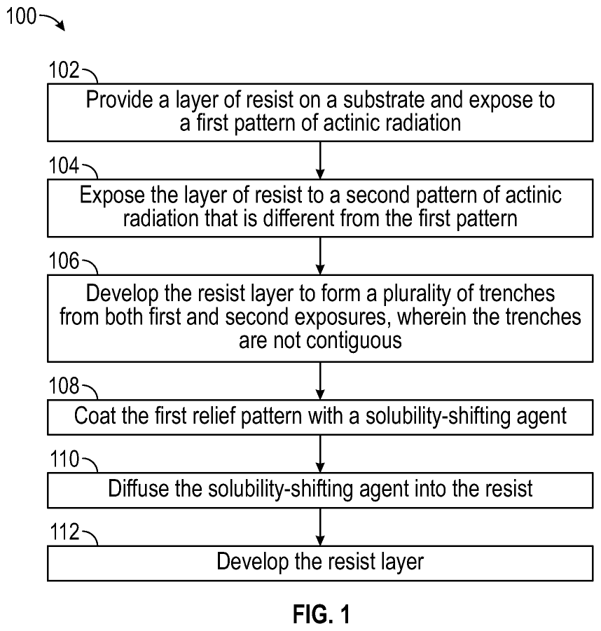

A method 100 in accordance with the present disclosure is shown in, and discussed with reference to, FIG. 1. Initially, method 100 includes, at block 102, exposing a first region in the resist layer to a first pattern of actinic radiation to form a first latent image. Block 104 includes exposing a second region in first resist to a second pattern of actinic radiation to form a second latent image adjacent to the first latent image. Block 106 includes treating the resist layer with a developer to form a first relief pattern comprising a plurality of features from both the first and second exposures, wherein the features are not contiguous but are separated by a first dimension. Block 108 includes coating the first relief pattern with a solubility shifting agent. The solubility shifting agent can be a solubilizing or hardening agent, based on the polarity of the first resist. Block 110 includes diffusing the solubility-shifting agent into the resist. Diffusion of the solubility shifting agent forms a solubility-shifted region at the sidewalls of the resist. Diffusion is controlled to achieve a distance that is at least half of the first dimension separating the features. Block 112 includes developing the resist again. The second develop removes the solubility-shifted region at the sidewalls of the resist and results in the features being contiguous rather than separated by the first distance.

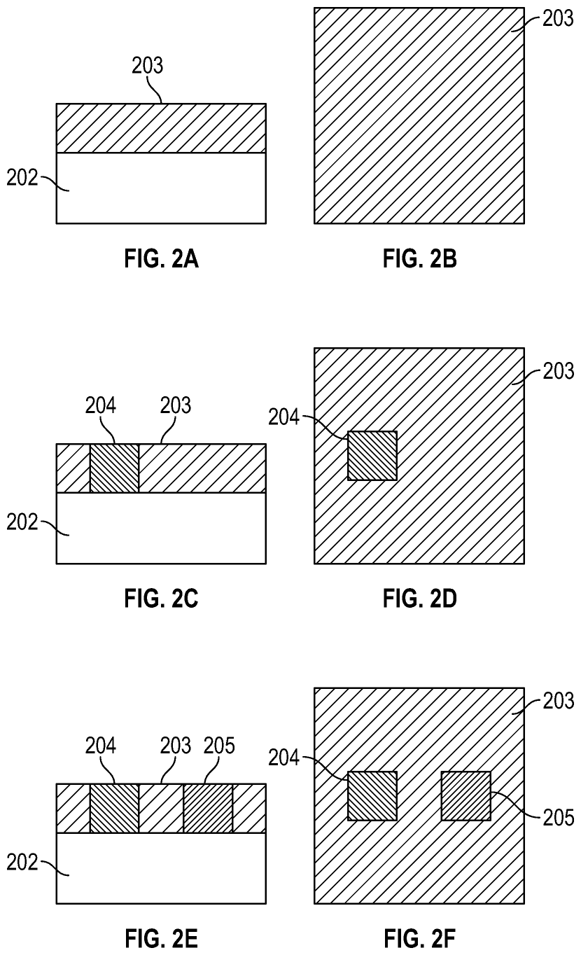

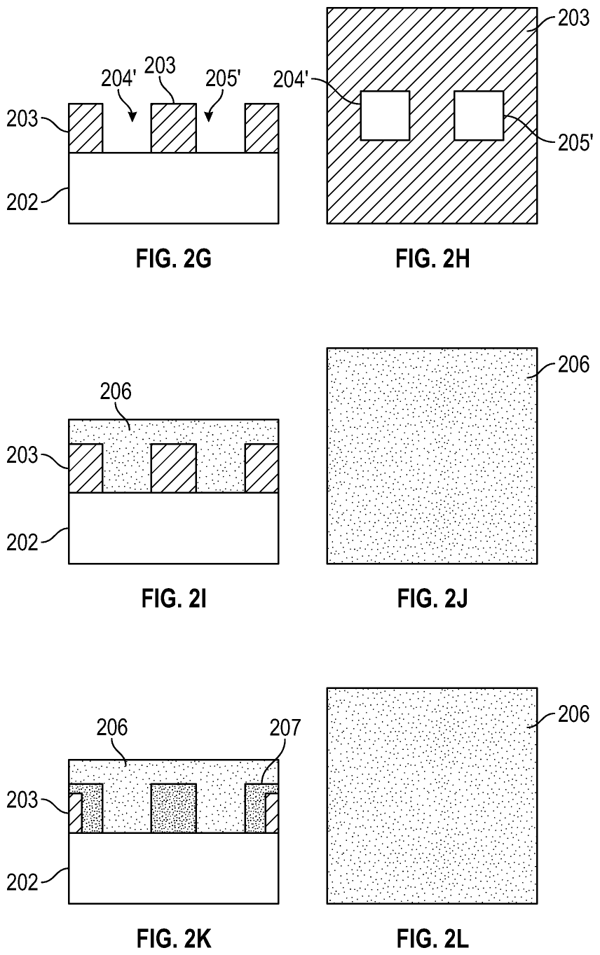

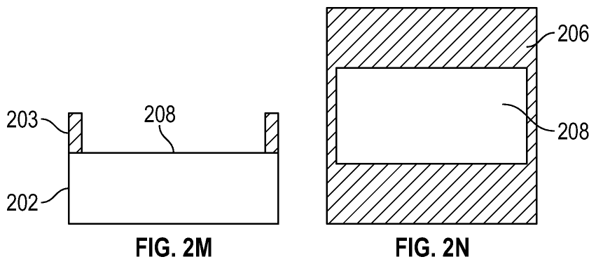

Schematic depictions of a coated substrate at various points during the method described above are shown in FIG. 2. FIGS. 2A, 2C, 2E, 2G, 2I, 2K, and 2M show cross-sectional schematic illustrations of coated substrates. FIGS. 2B, 2D, 2F, 2H, 2J, 2L, and 2N show corresponding top view schematic illustrations of coated substrates.

FIGS. 2A-B show a substrate 202 coated with a first resist 203. The first resist may be a photoresist. FIGS. 2C-D show a substrate 202 including a first latent image 204 formed in resist 203. In FIGS. 2E-2F, a second latent image 205 is formed in the first resist 203. FIGS. 2G-H show a coated substrate 202 after developing the first latent image 204 and second latent image 205 formed in the first resist layer 203 to form the first relief pattern with features 203 and trenches 204′ and 205′. FIGS. 2I-J show a substrate 202 including a first relief pattern with features 203 and trenches 204′ and 205′ coated with a solubility-shifting agent 206. FIGS. 2K-L show a substrate 202 including a first relief pattern in resist 203 where the solubility-shifting agent has been diffused into the resist to form solubility-shifted regions 207. Finally, FIGS. 2M-N show a coated substrate after the final development, which forms a single recessed feature 208 by stitching together the trenches. FIGS. 2A-2G are discussed in detail below.

At block 102 of method 100, a first resist layer is provided. The first resist may be a photoresist. A first resist layer 203 may be formed by layering the resist onto a substrate 202 as shown in FIGS. 2A-B FIGS. 2A-2B show an example of a first resist layer 203 on a substrate 202. Also, at block 102 of method 100, a first region on the first resist may be exposed to a first pattern of actinic radiation resulting in a first latent image 204 as shown in FIGS. 2C-D.

Generally, a resist is a chemically amplified photosensitive composition that comprises a polymer, a photoacid generator, and a solvent. In one or more embodiments, the first resist includes a polymer. The polymer may be any standard polymer typically used in resist material and may particularly be a polymer having acid-labile groups. For example, the polymer may be a polymer made from monomers including vinyl aromatic monomers such as styrene and p-hydroxystyrene, acrylate, methacrylate, norbornene, and combinations thereof. Monomers that include reactive functional groups may be present in the polymer in a protected form. For example, the —OH group of p-hydroxystyrene may be protected with a tert-butyloxycarbonyl protecting group. Such protecting group may alter the reactivity and solubility of the polymer included in the first resist. As will be appreciated by one having ordinary skill in the art, various protecting groups may be used for this reason. Acid-labile groups include, for example: tertiary alkyl ester groups, secondary or tertiary aryl ester groups, secondary or tertiary ester groups having a combination of alkyl and aryl groups, tertiary alkoxy groups, acetal groups, or ketal groups. Acid-labile groups are also commonly referred to in the art as “acid-decomposable groups”, “acid-cleavable groups,” “acid-cleavable protecting groups,” “acid-labile protecting groups,” “acid-leaving groups,” and “acid-sensitive groups.”

The acid-labile group which, on decomposition, forms a carboxylic acid on the polymer is preferably a tertiary ester group of the formula —C(O)OC(R¹)₃ or an acetal group of the formula —C(O)OC(R²)₂OR³, wherein: R¹ is each independently linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, each R¹ optionally including as part of its structure one or more groups chosen from —O—, —C(O)—, —C(O)—O—, or —S—, and any two R¹ groups together optionally forming a ring; R² is independently hydrogen, fluorine, linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably hydrogen, linear C₁₋₆ alkyl, branched C₃₋₆ alkyl, or monocyclic or polycyclic C₃₋₁₀ cycloalkyl, each of which is substituted or unsubstituted, each R² optionally including as part of its structure one or more groups chosen from —O—, —C(O)—, —C(O)—O—, or —S—, and the R² groups together optionally forming a ring; and R³ is linear C₁₋₂₀ alkyl, branched C₃₋₂₀ alkyl, monocyclic or polycyclic C₃₋₂₀ cycloalkyl, linear C₂₋₂₀ alkenyl, branched C₃₋₂₀ alkenyl, monocyclic or polycyclic C₃₋₂₀ cycloalkenyl, monocyclic or polycyclic C₆₋₂₀ aryl, or monocyclic or polycyclic C₂₋₂₀ heteroaryl, preferably linear C₁₋₆ alkyl, branched C₃₋₆ alkyl, or monocyclic or polycyclic C₃₋₁₀ cycloalkyl, each of which is substituted or unsubstituted, R³ optionally including as part of its structure one or more groups chosen from —O—, —C(O)—, —C(O)—O—, or —S—, and one R² together with R³ optionally forming a ring. Such monomer is typically a vinyl aromatic, (meth)acrylate, or norbornyl monomer. The total content of polymerized units comprising an acid-decomposable group which forms a carboxylic acid group on the polymer is typically from 10 to 100 mole %, more typically from 10 to 90 mole % or from 30 to 70 mole %, based on total polymerized units of the polymer.

The polymer can further include as polymerized a monomer comprising an acid-labile group, the decomposition of which group forms an alcohol group or a fluoroalcohol group on the polymer. Suitable such groups include, for example, an acetal group of the formula —COC(R²)₂OR³—, or a carbonate ester group of the formula —OC(O)O—, wherein R is as defined above. Such monomer is typically a vinyl aromatic, (meth)acrylate, or norbornyl monomer. If present in the polymer, the total content of polymerized units comprising an acid-decomposable group, the decomposition of which group forms an alcohol group or a fluoroalcohol group on the polymer, is typically from 10 to 90 mole %, more typically from 30 to 70 mole %, based on total polymerized units of the polymer.

In embodiments in which the first resist is a photoresist, the first resist includes a photoacid generator. The photoacid generator is a compound capable of generating an acid upon irradiation with actinic rays or radiation. The photoacid generator may be selected from known compounds capable of generating an acid upon irradiation with actinic rays or radiation which are used for a photoinitiator for cationic photopolymerization, a photoinitiator for radical photopolymerization, a photodecoloring agent for dyes, a photodiscoloring agent, a microresist, or the like, and a mixture thereof can be used. Examples of the photoacid generator include a diazonium salt, a phosphonium salt, a sulfonium salt, an iodonium salt, imidosulfonate, oxime sulfonate, diazodisulfone, disulfone, and o-nitrobenzyl sulfonate.

Suitable photoacids include onium salts, for example, triphenylsulfonium trifhioromethanesulfonate, (p-tert-butoxyphenyl)diphenylsulfonium tris(p-tert-butoxyphenyl) sulfonium trifhioromethanesulfonate, trifluoromethanesulfonate, triphenylsulfonium p-toluenesulfonate; di-t-butyphenyliodonium perfluorobutanesulfonate, and di-t-butyphenyliodonium camphorsulfonate. Non-ionic sulfonates and sulfonyl compounds are also known to function as photoacid generators, e.g., nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. Suitable non-polymerized photoacid generators are further described in U.S. Pat. No. 8,431,325 to Hashimoto et al. in column 37, lines 11-47 and columns 41-91. Other suitable sulfonate PAGs include sulfonated esters and sulfonyloxy ketones, nitrobenzyl esters, s-triazine derivatives, benzoin tosylate, t-butylphenyl α-(p-toluenesulfonyloxy)-acetate, and t-butyl α-(p-toluenesulfonyloxy)-acetate; as described in U.S. Pat. Nos. 4,189,323 and 8,431,325. PAGs that are onium salts typically comprise an anion having a sulfonate group or a non-sulfonate type group, such as a sulfonamidate group, a sulfonimidate group, a methide group, or a borate group.

The resist composition may optionally comprise a plurality of PAGs. The plural PAGs may be polymeric, non-polymeric, or may include both polymeric and non-polymeric PAGs. Preferably, each of the plurality of PAGs is non-polymeric. Preferably, when a plurality of PAGs are used, a first PAG comprises a sulfonate group on the anion and a second PAG comprises an anion that is free of sulfonate groups, such anion containing for example, a sulfonamidate group, a sulfonimidate group, a methide group, or a borate group such as described above.

Next, at block 104 of method 100, a second region in the first resist may be exposed to a second pattern of actinic radiation resulting in a second latent image 205 as shown in FIGS. 2E-F. After the actinic radiation is applied, the unexposed portions of the resist may have a different solubility than the exposed portions of the first resist.

At block 106 of method 100, the first resist may be rinsed with a first resist developer. Rinsing with the first resist developer will dissolve either the unexposed portion or the exposed portion. The dissolved portion may form trenches such as 204′ and 205′. The undissolved resist may form a first relief pattern composed of the first resist 203 and features 204′ and 205′ on the substrate 202 as shown in FIGS. 2G-H. The first relief pattern may include features of the first resist 203 separated by gaps characterized by a first dimension. Portions of the substrate may be exposed by the presence of the gaps of the first relief pattern.

The first relief pattern may be formed by layering the first resist onto a substrate and the developing the resist. The resist may be developed according to procedures known in the art, e.g., exposure to actinic radiation followed by rinsing with a first resist developer. In order to impart a shape, or relief pattern, in the developed resist, a mask may be used to block a portion of the resist from the actinic radiation. After the actinic radiation is applied, the unexposed portion of the resist may have a different solubility than the exposed portion of the resist. Subsequent rinsing with the first resist developer will dissolve either the unexposed portion or the exposed portion. A relief pattern provided when the unexposed portion of the resist remains after rinsing with a developer is a positive tone developed resist. In contrast, a relief pattern provided when the exposed portion of the resist remains after rinsing with a developer is a negative tone developed resist.

In one or more embodiments, the resist is a positive tone developed (PTD) resist. In such embodiments, the first relief pattern may include a polymer made from the above described monomers, wherein any monomers including a reactive functional group are protected. As such, a PTD first resist may be organic soluble, and thus the relief pattern may be provided by rinsing with a first resist developer that is basic. Suitable basic first resist developers include quaternary ammonium hydroxides, such as tetramethylammonium hydroxide (TMAH).

In other embodiments, the first resist is a negative resist. In such embodiments, the first relief pattern may include a polymer made from the above described monomers, wherein any monomers including a reactive functional group are not protected. Exposure to actinic radiation results in crosslinking of the polymer in areas of exposure, rendering the polymer insoluble to developers. The unexposed and thus uncrosslinked areas can then be removed using an appropriate developer to form the relief pattern.

In other embodiments, the first photoresist is a negative tone developed (NTD) photoresist. Similar to PTD photoresists, NTD photoresists may include a polymer made from the above described monomers, wherein any monomers including a reactive functional group are protected. As such, a NTD first photoresist may be organic soluble, but instead of developing the exposed areas with a first photoresist developer that is basic, the first relief pattern may be provided by rinsing the first resist with a resist developer including an organic solvent. Suitable organic solvents that may be used as a resist developer include n-butyl acetate (NBA) and 2-heptanone. The tone of the resist (i.e., PTD vs. negative vs. NTD) may influence the subsequent chemistry applied to the first relief pattern.

In other embodiments, the first resist optionally contains other additives, wherein other additives include at least one of a resin having at least either a fluorine atom or a silicon atom, a basic compound, a surfactant, an onium carboxylate, dye, a plasticizer, a photosensitizer, a light absorbent, an alkali-soluble resin, a dissolution inhibitor, and a compound for accelerating dissolution in a developer.

As previously described, the first relief pattern may include features of the first resist 203 separated by gaps. In one or more embodiments, the features of the first resist 203 of the first relief pattern may have a thickness of about 300 to 3000 Å. The gaps separating the features of the first resist 203 may leave portions of the substrate exposed.

In some embodiments, the first relief pattern is stabilized prior to coating with the solubility-shifting agent. Various resist stabilization techniques, also known as freeze processes, have been proposed such as ion implantation, UV curing, thermal hardening, thermal curing and chemical curing. Techniques are described, for example, in US2008/0063985A1, US 2008/0199814A1 and US 2010/0330503A1.

At block 108 of method 100, the first relief pattern is coated with a solubility-shifting agent. A coated substrate layered with a first relief pattern 203 and a solubility-shifting agent 206 are shown in FIGS. 2I-J. A coated substrate in accordance with block 108 is shown in FIGS. 2I-2J. The solubility-shifting agent 206 is shown as a coating over the first relief pattern 203. The thickness of the solubility-shifting agent coating is not particularly limited and may be altered based on the desired line cut width. The solubility-shifting agent may be a material that is absorbed into the first resist via a bake, and in some instances herein may be referred to as an “absorbed material.” The process of absorbing the solubility-shifting agent into the first resist is described in detailed below.

At block 110 of method 100, the solubility-shifting agent 206 may diffuse into the first relief pattern 203 to form solubility-shifted region 207 as shown in FIG. 2K.

In one or more embodiments, the solubility-shifted region of the resist is developed by first being exposed to actinic radiation, and then being exposed to a specific developer. In other embodiments, the solubility-shifted region of the first resist is only exposed to the specific developer. The specific developer may depend on the tone of the first resist. For example, if the resist is a positive tone developed resist, the specific developer may be a base such as tetramethylammonium hydroxide. On the other hand, if the first resist is a negative tone developed resist, the specific developer may be a nonpolar organic solvent, such as n-butyl acetate or 2-heptanone.

As described previously, the thickness of the solubility-shifted region may correspond to at least half of the width of the gap separating the features 203. The thickness of the solubility-shifting agent coating is not particularly limited and may be altered based on the desired final pattern parameters. The solubility-shifting agent may be a material that is absorbed into the resist via a bake, and in some instances herein may be referred to as an “absorbed material.” The process of absorbing the solubility-shifting agent into the resist is described in detailed below.

The composition of the solubility-shifting agent may depend on the tone of the resist. Generally, the solubility-shifting agent may be any chemical that activates with light or heat. For example, when the resist is a PTD resist, the solubility-shifting agent may include an acid or thermal acid generator.

The acid or generated acid in the case of a thermal acid generator (TAG) should be sufficient with heat to cause cleavage of the bonds of acid-decomposable groups of the polymer in a surface region of the first resist pattern to cause increased solubility of the first resist polymer in a specific developer to be applied. The acid or TAG is typically present in the composition in an amount of from about 0.01 to about 20 wt % based on the total solids of the trimming composition.

Preferable acids are organic acids including non-aromatic acids and aromatic acids, each of which can optionally have fluorine substitution. Suitable organic acids include, for example: carboxylic acids such as alkanoic acids, including formic acid, acetic acid, propionic acid, butyric acid, dichloroacetic acid, trichloroacetic acid, perfluoroacetic acid, perfluorooctanoic acid, oxalic acid malonic acid and succinic acid; hydroxyalkanoic acids, such as citric acid; aromatic carboxylic acids such as benzoic acid, fluorobenzoic acid, hydroxybenzoic acid and naphthoic acid; organic phosphorus acids such as dimethylphosphoric acid and dimethylphosphinic acid; and sulfonic acids such as optionally fluorinated alkylsulfonic acids including methanesulfonic acid, trifluoromethanesulfonic acid, ethanesulfonic acid, 1-butanesulfonic acid, 1-perfluorobutanesulfonic acid, 1,1,2,2-tetrafluorobutane-1-sulfonic acid, 1,1,2,2-tetrafluoro-4-hydroxybutane-1-sulfonic acid, 1-pentanesulfonic acid, 1-hexanesulfonic acid, and 1-heptanesulfonic acid.

Exemplary aromatic acids that are free of fluorine include wherein aromatic acids of the general formula (I):

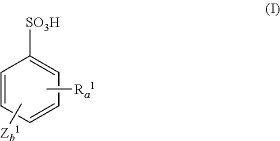

wherein: R1 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z1 independently represents a group chosen from carboxyl, hydroxy, nitro, cyano, C1 to C5 alkoxy, formyl and sulfonic acid; a and b are independently an integer from 0 to 5; and a+b is 5 or less.

Exemplary aromatic acids may be of the general formula (II):

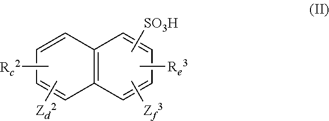

wherein: R2 and R3 each independently represents a substituted or unsubstituted C1-C20 alkyl group, a substituted or unsubstituted C5-C16 aryl group or a combination thereof, optionally containing one or more group chosen from carbonyl, carbonyloxy, sulfonamido, ether, thioether, a substituted or unsubstituted alkylene group, or a combination thereof; Z2 and Z3 each independently represents a group chosen from carboxyl, hydroxy, nitro, cyano, C1 to C5 alkoxy, formyl and sulfonic acid; c and d are independently an integer from 0 to 4; c+d is 4 or less; e and f are independently an integer from 0 to 3; and e+f is 3 or less.

Additional aromatic acids that may be included in the solubility-shifting agent include those the general formula (III) or (IV):

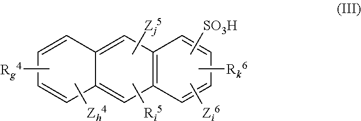

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 2; i+j is 2 or less; k and l are independently an integer from 0 to 3; and k+l is 3 or less;

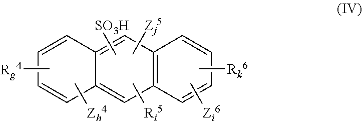

wherein: R4, R5 and R6 each independently represents a substituted or unsubstituted C1-C20 alkyl group, a substituted or unsubstituted C5-C12 aryl group or a combination thereof, optionally containing one or more group chosen from carbonyl, carbonyloxy, sulfonamido, ether, thioether, a substituted or unsubstituted alkylene group, or a combination thereof; Z4, Z5 and Z6 each independently represents a group chosen from carboxyl, hydroxy, nitro, cyano, C1 to C5 alkoxy, formyl and sulfonic acid; g and h are independently an integer from 0 to 4; g+h is 4 or less; i and j are independently an integer from 0 to 1; i+j is 1 or less; k and l are independently an integer from 0 to 4; and k+1 is 4 or less.

Suitable aromatic acids may alternatively be of the general formula (V):

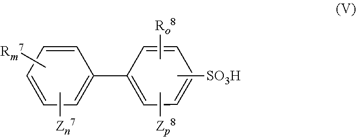

wherein: R7 and R8 each independently represents a substituted or unsubstituted C1-C20 alkyl group, a substituted or unsubstituted C5-C14 aryl group or a combination thereof, optionally containing one or more group chosen from carboxyl, carbonyl, carbonyloxy, sulfonamido, ether, thioether, a substituted or unsubstituted alkylene group, or a combination thereof; Z7 and Z8 each independently represents a group chosen from hydroxy, nitro, cyano, C1 to C5 alkoxy, formyl and sulfonic acid; m and n are independently an integer from 0 to 5; m+n is 5 or less; o and p are independently an integer from 0 to 4; and o+p is 4 or less.

Additionally, exemplary aromatic acids may have the general formula (VI):

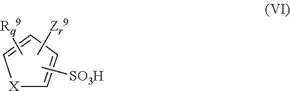

wherein: X is O or S; R9 independently represents a substituted or unsubstituted C1-C20 alkyl group, a substituted or unsubstituted C5-C20 aryl group or a combination thereof, optionally containing one or more group chosen from carbonyl, carbonyloxy, sulfonamido, ether, thioether, a substituted or unsubstituted alkylene group, or a combination thereof; Z9 independently represents a group chosen from carboxyl, hydroxy, nitro, cyano, C1 to C5 alkoxy, formyl and sulfonic acid; q and r are independently an integer from 0 to 3; and q+r is 3 or less.

In one or more embodiments, the acid is a free acid having fluorine substitution. Suitable free acids having fluorine substitution may be aromatic or nonaromatic. For example, free acid having fluorine substitution that may be used as solubility-shifting agent include, but are not limited to the following:

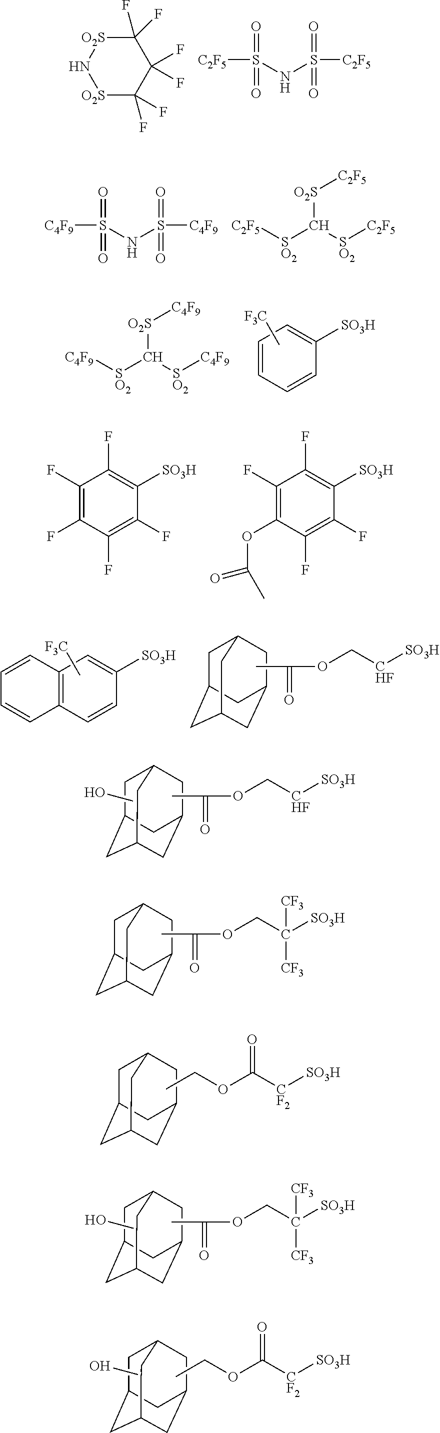

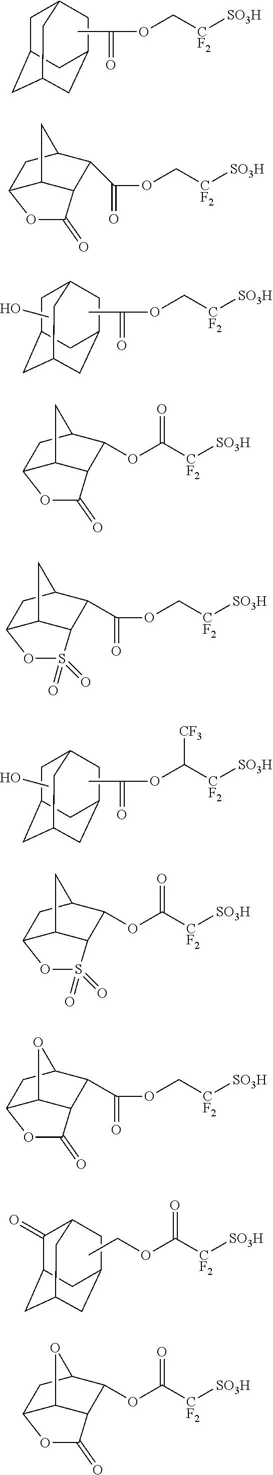

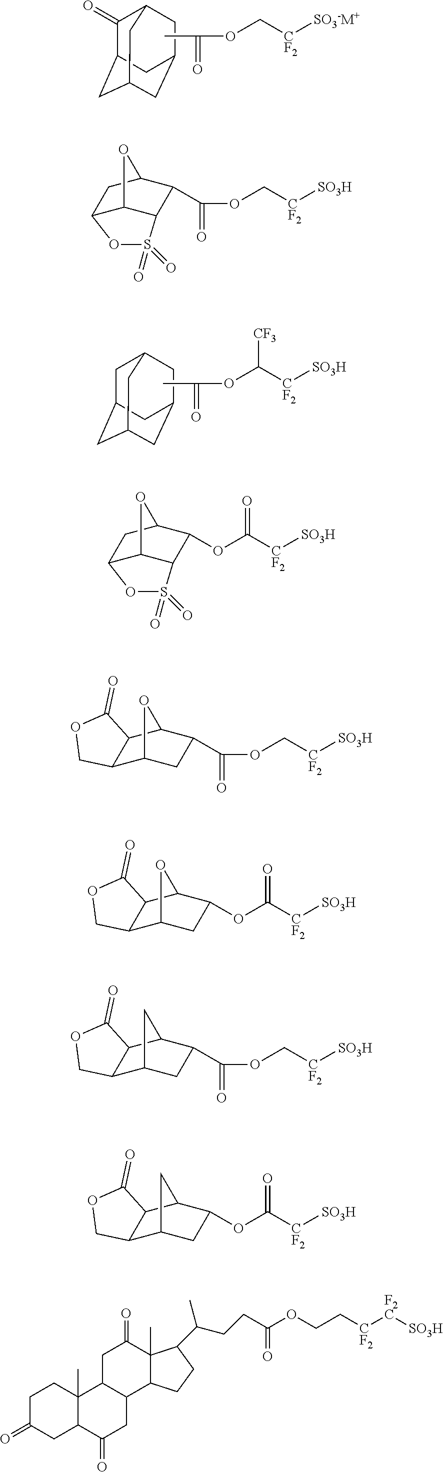

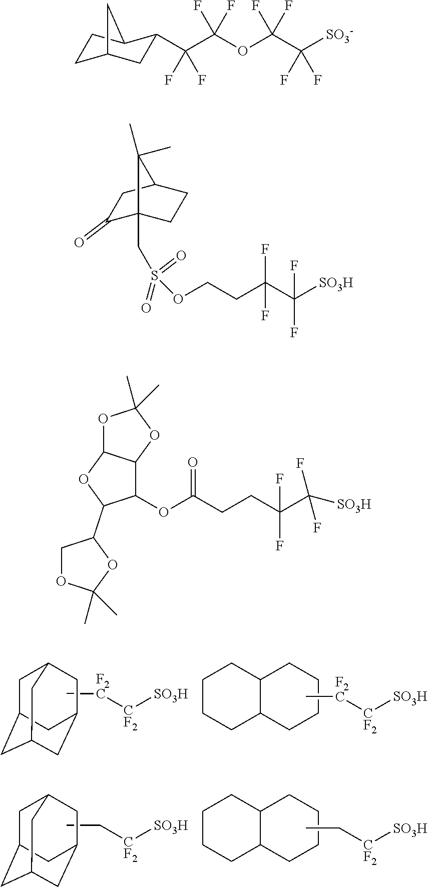

Suitable TAGs include those capable of generating a non-polymeric acid as described above. The TAG can be non-ionic or ionic. Suitable nonionic thermal acid generators include, for example, cyclohexyl trifluoromethyl sulfonate, methyl trifluoromethyl sulfonate, cyclohexyl p-toluenesulfonate, methyl p-toluenesulfonate, cyclohexyl 2,4,6-triisopropylbenzene sulfonate, nitrobenzyl esters, benzoin tosylate, 2-nitrobenzyl tosylate, tris(2,3-dibromopropyl)-1,3,5-triazine-2,4,6-trione, alkyl esters of organic sulfonic acids, p-toluenesulfonic acid, dodecylbenzenesulfonic acid, oxalic acid, phthalic acid, phosphoric acid, camphorsulfonic acid, 2,4,6-trimethylbenzene sulfonic acid, triisopropylnaphthalene sulfonic acid, 5-nitro-o-toluene sulfonic acid, 5-sulfosalicylic acid, 2,5-dimethylbenzene sulfonic acid, 2-nitrobenzene sulfonic acid, 3-chlorobenzene sulfonic acid, 3-bromobenzene sulfonic acid, 2-fluorocaprylnaphthalene sulfonic acid, dodecylbenzene sulfonic acid, 1-naphthol-5-sulfonic acid, 2-methoxy-4-hydroxy-5-benzoyl-benzene sulfonic acid, and their salts, and combinations thereof. Suitable ionic thermal acid generators include, for example, dodecylbenzenesulfonic acid triethylamine salts, dodecylbenzenedisulfonic acid triethylamine salts, p-toluene sulfonic acid-ammonium salts, p-toluene sulfonic acid-pyridinium salts, sulfonate salts, such as carbocyclic aryl and heteroaryl sulfonate salts, aliphatic sulfonate salts, and benzenesulfonate salts. Compounds that generate a sulfonic acid upon activation are generally suitable. Preferred thermal acid generators include p-toluenesulfonic acid ammonium salts, and heteroaryl sulfonate salts.

Preferably, the TAG is ionic with a reaction scheme for generation of a sulfonic acid as shown below:

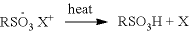

wherein RSO₃⁻ is the TAG anion and X⁺ is the TAG cation, preferably an organic cation. The cation can be a nitrogen-containing cation of the general formula (I):

(BH)⁺ (I)
which is the monoprotonated form of a nitrogen-containing base B. Suitable nitrogen-containing bases B include, for example: optionally substituted amines such as ammonia, difluoromethylammonia, C1-20 alkyl amines, and C3-30 aryl amines, for example, nitrogen-containing heteroaromatic bases such as pyridine or substituted pyridine (e.g., 3-fluoropyridine), pyrimidine and pyrazine; nitrogen-containing heterocyclic groups, for example, oxazole, oxazoline, or thiazoline. The foregoing nitrogen-containing bases B can be optionally substituted, for example, with one or more group chosen from alkyl, aryl, halogen atom (preferably fluorine), cyano, nitro and alkoxy. Of these, base B is preferably a heteroaromatic base.

Base B typically has a pKa from 0 to 5.0, or between 0 and 4.0, or between 0 and 3.0, or between 1.0 and 3.0. As used herein, the term “pKa” is used in accordance with its art-recognized meaning, that is, pKa is the negative log (to the base 10) of the dissociation constant of the conjugate acid (BH)⁺ of the basic moiety (B) in aqueous solution at about room temperature. In certain embodiments, base B has a boiling point less than about 170° C., or less than about 160° C., 150° C., 140° C., 130° C., 120° C., 110° C., 100° C. or 90° C.

Exemplary suitable nitrogen-containing cations (BH)⁺ include NH₄⁺, CF₂HNH₂⁺, CF₃CH₂NH₃⁺, (CH₃)₃NH⁺, (C₂H₅)₃NH⁺, (CH₃)₂(C₂H₅)NH⁺ and the following:

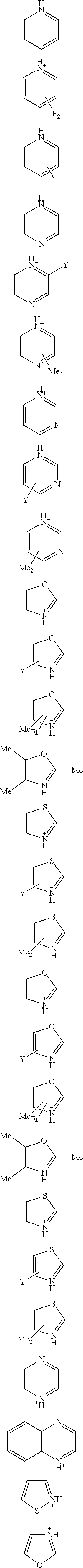

in which Y is alkyl, preferably, methyl or ethyl.

In one or more embodiments, the solubility-shifting agents may be an acid such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; acid generators such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; or a combination thereof.

Alternatively, when the resist is an NTD resist, the solubility-shifting agent may include a base or base generator. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl) propane, Troger's base, a hindered amine such as diazabicycloundecene (DBU) or diazabicyclononene (DBN), amides like tert-butyl 1,3-dihydroxy-2-(hydroxymethyl) propan-2-ylcarbamate and ter-butyl 4-hydroxypiperidine-1-carboxylate or; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups each having 1 to about 8 carbon atoms, and preferably 1 to about 5 carbon atoms such as hydroxymethyl, hydroxyethyl and hydroxybutyl groups. Specific examples of hydroxyamines include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quarternary ammonium salt, nifedipine, carbamate, and combinations thereof. Exemplary thermal base generators include o-{(.beta.-(dimethylamino)ethyl)aminocarbonyl}benzoic acid, o-{(.gamma.-(dimethylamino) propyl)aminocarbonyl}benzoic acid, 2,5-bis{(.beta.-(dimethylamino)ethyl)aminocarbonyl}terephthalic acid, 2,5-bis{(.gamma.-(dimethylamino) propyl)aminocarbonyl}terephthalic acid, 2,4-bis{(.beta.-(dimethylamino)ethyl)aminocarbonyl}isophthalic acid, 2,4 bis {(.gamma.-(dimethylamino) propyl)aminocarbonyl}isophthalic acid, and combinations thereof. In embodiments in which the solubility-shifting agent is a base or base generator the resist may be a non-self-aligned resist on hardmask.

In one or more embodiments, the solubility-shifting agent includes a solvent. As described above, in one or more embodiments the solubility-shifting agent is absorbed into the first relief pattern. Accordingly, the solvent may be any suitable solvent that may facilitate absorption into the first relief pattern, provided that it does not dissolve the resist. The solvent included in the absorbed material may depend on the tone of the resist. For example, a solubility-shifting agent meant to be absorbed into a PTD resist may include a solvent such as methyl isobutyl carbinol (MIBC), decane, isobutyl isobutyrate, isoamyl ether, and combinations thereof. In one or more embodiments, the solvent includes MIBC and a cosolvent. In such embodiments, the MIBC may be included in the solvent in an amount ranging from about 60 to about 99%, based on the total volume of solvent. Accordingly, the cosolvent may be included in amount ranging from about 1 to about 40%, based on the total volume of solvent.

When the first resist is formed from a vinyl aromatic-based polymer, as is typical for KrF and EUV photoresists, and the resist is developed as a PTD resist, the solvent system preferably comprises one or more non-polar organic solvents. The term “non-polar organic-based” means that the solvent system includes greater than 50 wt % of combined non-polar organic solvents based on total solvents of the solubility-shifting agent composition, more typically greater than 70 wt %, greater than 85 wt % or 100 wt %, combined non-polar organic solvents, based on total solvents of the solubility-shifting agent composition. The non-polar organic solvents are typically present in the solvent system in a combined amount of from 70 to 98 wt %, preferably 80 to 95 wt %, more preferably from 85 to 98 wt %, based on the solvent system.

Suitable non-polar solvents include, for example, ethers, hydrocarbons, and combinations thereof, with ethers being preferred. Suitable ether solvents include, for example, alkyl monoethers and aromatic monoethers, particularly preferred of which are those having a total carbon number of from 6 to 16. Suitable alkyl monoethers include, for example, 1,4-cineole, 1,8-cineole, pinene oxide, di-n-propyl ether, diisopropyl ether, di-n-butyl ether, di-n-pentyl ether, diisoamyl ether, dihexyl ether, diheptyl ether, and dioctyl ether, with diisoamyl ether being preferred. Suitable aromatic monoethers include, for example, anisole, ethylbenzyl ether, diphenyl ether, dibenzyl ether and phenetole, with anisole being preferred. Suitable aliphatic hydrocarbons include, for example, n-heptane, 2-methylheptane, 3-methylheptane, 3,3-dimethylhexane, 2,3,4-trimethylpentane, n-octane, n-nonane, n-decane, and fluorinated compounds such as perfluoroheptane. Suitable aromatic hydrocarbons include, for example, benzene, toluene, and xylene.

In some embodiments, the solvent system further includes one or more alcohol and/or ester solvents. For certain compositions, an alcohol and/or ester solvent may provide enhanced solubility with respect to the solid components of the composition. Suitable alcohol solvents include, for example: straight, branched or cyclic C₄₋₉ monohydric alcohol such as 1-butanol, 2-butanol, isobutyl alcohol, tert-butyl alcohol, 3-methyl-1-butanol, 1-pentanol, 2-pentanol, 4-methyl-2-pentanol, 1-hexanol, 1-heptanol, 1-octanol, 2-hexanol, 2-heptanol, 2-octanol, 3-hexanol, 3-heptanol, 3-octanol, 4-octanol, 2,2,3,3,4,4-hexafluoro-1-butanol, 2,2,3,3,4,4,5,5-octafluoro-1-pentanol, and 2,2,3,3,4,4,5,5,6,6-decafluoro-1-hexanol; and C₅₋₉ fluorinated diols such as 2,2,3,3,4,4-hexafluoro-1,5-pentanediol, 2,2,3,3,4,4,5,5-octafluoro-1,6-hexanediol, and 2,2,3,3,4,4,5,5,6,6,7,7-dodecafluoro-1,8-octanediol. The alcohol solvent is preferably a C₄₋₉ monohydric alcohol, with 4-methyl-2-pentanol being preferred. Suitable ester solvents include, for example, alkyl esters having a total carbon number of from 4 to 10, for example, alkyl propionates such as n-butyl propionate, n-pentyl propionate, n-hexyl propionate, and n-heptyl propionate, and alkyl butyrates such as n-butyl butyrate, isobutyl butyrate, and isobutyl isobutyrate. The one or more alcohol and/or ester solvents if used in the solvent system are typically present in a combined amount of from 2 to 50 wt %, more typically in an amount of from 2 to 30 wt %, based on the solvent system.

The solvent system can also include one or more additional solvents chosen, for example, from one or more of: ketones such as 2,5-dimethyl-4-hexanone and 2,6-dimethyl-4-heptanone; and polyethers such as dipropylene glycol monomethyl ether and tripropylene glycol monomethyl ether. Such additional solvents, if used, are typically present in a combined amount of from 1 to 20 wt % based on the solvent system.

When the first resist is formed from a vinyl aromatic-based polymer, a particularly preferred organic-based solvent system includes one or more monoether solvents in a combined amount of from 70 to 98 wt % based on the solvent system, and one or more alcohol and/or ester solvents in a combined amount of from 2 to 30 wt % based on the solvent system. The solvent system is typically present in the overcoat composition in an amount of from 90 to 99 wt %, preferably from 95 to 99 wt %, based on the overcoat composition.

In one or more embodiments in which, the resist is a NTD resist, suitable organic solvents include, but are not limit to, n-butyl acetate, 2-heptanone, propylene glycol methyl ether, propylene glycol methyl ether acetate, and combinations thereof.

In one or more embodiments, the solubility-shifting agent is coated over the first relief pattern. To coat the first relief pattern, the solubility-shifting agent may include a matrix polymer. Any matrix polymer commonly used in the art may be included in the solubility-shifting material. The matrix polymer can be formed from one or more monomers chosen, for example, from those having an ethylenically unsaturated polymerizable double bond, such as: (meth)acrylate monomers such as isopropyl(meth)acrylate and n-butyl(meth)acrylate; (meth)acrylic acid; vinyl aromatic monomers such as styrene, hydroxystyrene, vinyl naphthalene and acenaphthylene; vinyl alcohol; vinyl chloride; vinyl pyrrolidone; vinyl pyridine; vinyl amine; vinyl acetal; and combinations thereof. In some embodiments, the polymer contains one or more functional groups chosen, for example, from hydroxy, acid groups such as carboxyl, sulfonic acid and sulfonamide, silanol, fluoroalcohol such as hexafluoroisopropyl alcohol [—C(CF₃)₂OH], anhydrates, lactones, esters, ethers, allylamine, pyrrolidones and combinations thereof. The polymer can be a homopolymer or a copolymer having a plurality of distinct repeat units, for example, two, three, four or more distinct repeat units. In one aspect, the repeat units of the polymer are all formed from (meth)acrylate monomers, are all formed from (vinyl) aromatic monomers or are all formed from (meth)acrylate monomers and (vinyl) aromatic monomers. When the polymer includes more than one type of repeat unit, it typically takes the form of a random copolymer. In particular embodiments, the matrix polymer may be a t-butyl acrylate (TBA)/p-hydroxystyrene (PHS) copolymer, a butyl acrylate (BA)/PHS copolymer, a TBA/methacrylic acid (MAA) copolymer, a BA/MAA copolymer, a PHS/methacrylate (MA) copolymer, and combinations thereof.

The solubility-shifting agent compositions typically include a single polymer, but can optionally include one or more additional polymers. The content of the polymer in the composition will depend, for example, on the target thickness of the layer, with a higher polymer content being used when thicker layer is desired. The polymer is typically present in the pattern trimming composition in an amount of from 80 to 99.9 wt %, more typically from 90 to 99 wt %, or 95 to 99 wt %, based on total solids of the trimming composition. The weight average molecular weight (Mw) of the polymer is typically less than 400,000, preferably from 3000 to 50,000, more preferably from 3000 to 25,000, as measured by GPC versus polystyrene standards. Typically, the polymer will have a polydispersity index (PDI=Mw/Mn) of 3 or less, preferably 2 or less, as measured by GPC versus polystyrene standards.

Suitable polymers for use in the trimming compositions are commercially available and/or can readily be made by persons skilled in the art. For example, the polymer may be synthesized by dissolving selected monomers corresponding to units of the polymer in an organic solvent, adding a radical polymerization initiator thereto, and effecting heat polymerization to form the polymer. Examples of suitable organic solvents that can be used for polymerization of the polymer include, for example, toluene, benzene, tetrahydrofuran, diethyl ether, dioxane, ethyl lactate and methyl isobutyl carbinol. Suitable polymerization initiators include, for example, 2,2′-azobisisobutyronitrile (AIBN), 2,2′-azobis(2,4-dimethylvaleronitrile), dimethyl 2,2-azobis(2-methylpropionate), benzoyl peroxide and lauroyl peroxide.

Solubility-shifting agents including a matrix polymer may be coated over the first relief pattern according to methods known in the art. Typically, a solubility-shifting agent that includes a matrix polymer may coated over the first relief pattern by spin coating. The solids content of the solubility-agent may be tailored to provide a film of a desired thickness of the solubility-shifting agent over the first relief pattern. For example, the solids content of the solubility-shifting agent solution can be adjusted to provide a desired film thickness based upon the specific coating equipment utilized, the viscosity of the solution, the speed of the coating tool and the amount of time allowed for spinning. A typical thickness for the composition is from about 200 to about 1500 Å.

In one or more embodiments, a solubility-shifting agent includes an active material (i.e., and acid, acid generator, base or base generator), a solvent, and a matrix polymer as previously described. A typical formulation for such solubility-shifting agent may include about 1 to about 10 wt % solids and about 90 to about 99 wt % solvent, based on the total weight of the solubility shifting agent, where the solids include the active material and the matrix polymer. Within the solids content, the active material may be included in an amount ranging from about 1 to about 5 wt %.

The solubility-shifting agent may include additives having various purposes, depending on the particular chemistry being used. In one or more embodiments, a surfactant may be included in the solubility-shifting agent. A surfactant may be included in the solubility-shifting agent to help with coating quality, especially when needing to fill thin gaps between features of the resist. Any suitable surfactant known in the art may be included in the solubility-shifting agent.

As noted above, in one or more embodiments, the solubility-shifting agent is absorbed into the first relief pattern. Absorption of the solubility-shifting agent into the first relief pattern may be achieved by performing a thermal pretreatment such as a bake. The bake may be a soft bake. The temperature and time of the soft bake may depend on the identity of the first resist, and the desired amount of diffusion of the solubility-shifting agent into the first resist. Typically, a soft bake may be performed for about 30 to 90 seconds at a temperature ranging from about 50 to about 150° C.

After diffusion into the first resist, a coating layer that does not include any active solubility-shifting material, may remain on the first resist. In one or more embodiments, the coating layer may be removed by a rinse. The rinse may be accomplished by rinsing the coated substrate with a solvent that dissolves the coating layer but does not dissolve the first resist. The rinse may be carried out using any suitable method, for example, by dipping a substrate in a bath filled with the solvent for a fixed time (dip method), by raising the solvent on a substrate surface by the effect of a surface tension and keeping it still for a fixed time, thereby dissolving the coating layer (puddle method), by spraying the solvent on a substrate surface (spray method), or by continuously ejecting the solvent on a substrate rotating at a constant speed while scanning the solvent ejecting nozzle at a constant rate (dynamic dispense method).

The composition of the solubility-shifting agent may depend on the tone of the resist. Generally, the solubility-shifting agent may be any chemical that activates with light or heat. For example, when the resist is a PTD resist, the solubility-shifting agent may include an acid or acid generator. In such embodiments, suitable solubility-shifting agents include, but are not limited to, acids such as trifluoromethanesulfonic acid, perfluoro-1-butanesulfonic acid, p-toluenesulfonic acid, 4-dodecylbenzenesulfonic acid, 2,4-dinitrobenzenesulfonic acid, and 2-trifluoromethylbenzenesulfonic acid; acid generators such as triphenylsulfonium antimonate, pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, and 4-t-butylphenyltetramethylenesulfonium 4,4,5,5,6,6-hexafluorodihydro-4H-1,3,2-dithiazine 1,1,3,3-tetraoxide; and combinations thereof.

Alternatively, when the resist is an NTD resist, the solubility-shifting agent may include a base or base generator. In such embodiments, suitable solubility-shifting agents include, but are not limited to, hydroxides, carboxylates, amines, imines, amides, and mixtures thereof. Specific examples of bases include ammonium carbonate, ammonium hydroxide, ammonium hydrogen phosphate, ammonium phosphate, tetramethylammonium carbonate, tetramethylammonium hydroxide, tetramethylammonium hydrogen phosphate, tetramethylammonium phosphate, tetraethylammonium carbonate, tetraethylammonium hydroxide, tetraethylammonium hydrogen phosphate, tetraethylammonium phosphate, and combinations thereof. Amines include aliphatic amines, cycloaliphatic amines, aromatic amines and heterocyclic amines. The amine may be a primary, secondary or tertiary amine. The amine may be a monoamine, diamine or polyamine. Suitable amines may include C1-30 organic amines, imines, or amides, or may be a C1-30 quaternary ammonium salt of a strong base (e.g., a hydroxide or alkoxide) or a weak base (e.g., a carboxylate). Exemplary bases include amines such as tripropylamine, dodecylamine, tris(2-hydroxypropyl)amine, tetrakis(2-hydroxypropyl)ethylenediamine; aryl amines such as diphenylamine, triphenylamine, aminophenol, and 2-(4-aminophenyl)-2-(4-hydroxyphenyl) propane, Troger's base, a hindered amine such as diazabicycloundecene (DBU) or diazabicyclononene (DBN), amides like tert-butyl 1,3-dihydroxy-2-(hydroxymethyl) propan-2-ylcarbamate and tert-butyl 4-hydroxypiperidine-1-carboxylateor; or ionic quenchers including quaternary alkyl ammonium salts such as tetrabutylammonium hydroxide (TBAH) or tetrabutylammonium lactate. In another embodiment, the amine is a hydroxyamine. Examples of hydroxyamines include hydroxyamines having one or more hydroxyalkyl groups each having 1 to about 8 carbon atoms, and preferably 1 to about 5 carbon atoms such as hydroxymethyl, hydroxyethyl and hydroxybutyl groups. Specific examples of hydroxyamines include mono-, di- and tri-ethanolamine, 3-amino-1-propanol, 2-amino-2-methyl-1-propanol, 2-amino-2-ethyl-1,3-propanediol, tris(hydroxymethyl)aminomethane, N-methylethanolamine, 2-diethylamino-2-methyl-1-propanol and triethanolamine.

Suitable base generators may be thermal base generators. A thermal base generator forms a base upon heating above a first temperature, typically about 140° C. or higher. The thermal base generator may include a functional group such as an amide, sulfonamide, imide, imine, O-acyl oxime, benzoyloxycarbonyl derivative, quaternary ammonium salt, nifedipine, carbamate, and combinations thereof. Exemplary thermal base generators include o-{(.beta.-(dimethylamino)ethyl)aminocarbonyl}benzoic acid, o-{(.gamma.-(dimethylamino) propyl)aminocarbonyl}benzoic acid, 2,5-bis {(.beta.-(dimethylamino)ethyl)aminocarbonyl}terephthalic acid, 2,5-bis{(.gamma.-(dimethylamino) propyl)aminocarbonyl}terephthalic acid, 2,4-bis{(.beta.-(dimethylamino)ethyl)aminocarbonyl}isophthalic acid, 2,4-bis{(.gamma.-(dimethylamino) propyl)aminocarbonyl}isophthalic acid, and combinations thereof.

In one or more embodiments, the solubility-shifting agent includes a solvent. As described above, in one or more embodiments the solubility-shifting agent is absorbed into the first relief pattern. Accordingly, the solvent may be any suitable solvent that may facilitate absorption into the first relief pattern, provided that it does not dissolve the resist. The solvent included in the absorbed material may depend on the tone of the resist. For example, a solubility-shifting agent meant to be absorbed into a PTD resist may include a polar protic solvent such as methyl isobutyl carbinol (MIBC), decane, isobutyl isobutyrate, isoamyl ether, and combinations thereof. In particular embodiments, the solvent includes MIBC and a cosolvent. In such embodiments, the MIBC may be included in the solvent in an amount ranging from 60 to 99%, based on the total volume of solvent. Accordingly, the cosolvent may be included in amount ranging from 1 to 40%, based on the total volume of solvent.

In one or more embodiments, the resist is a NTD resist, and the solvent is a nonpolar organic solvent. Suitable nonpolar organic solvents include, but are not limit to, n-butyl acetate, 2-heptanone, propylene glycol methyl ether, propylene glycol methyl ether acetate, and combinations thereof.

At block 112 of method 100, the deposited layer of the solubility-shifting agent 206 and the solubility-shifting region of resist 207 may be developed using a specific developer as shown in FIGS. 2M and 2N. Accordingly, dissolution of the solubility-shifted region may result in the formation of trenches 208 between the first relief pattern 203 in which the substrate 202 is exposed.

Method 100 represents one possible embodiment and is not intended to limit the scope of the present invention. As will be appreciated by one of ordinary skill in the art, the present invention may encompass various alternative methods, such as, for example, methods in which the solubility-shifting agent is diffused into, and changes the solubility of a region of a first resist, for example a resist as describe above with reference to method 100, and a second resist is then applied to complete an anti-spacer process rather. In such alternate embodiments, the components and techniques used in the methods may be as previously described with reference to method 100.

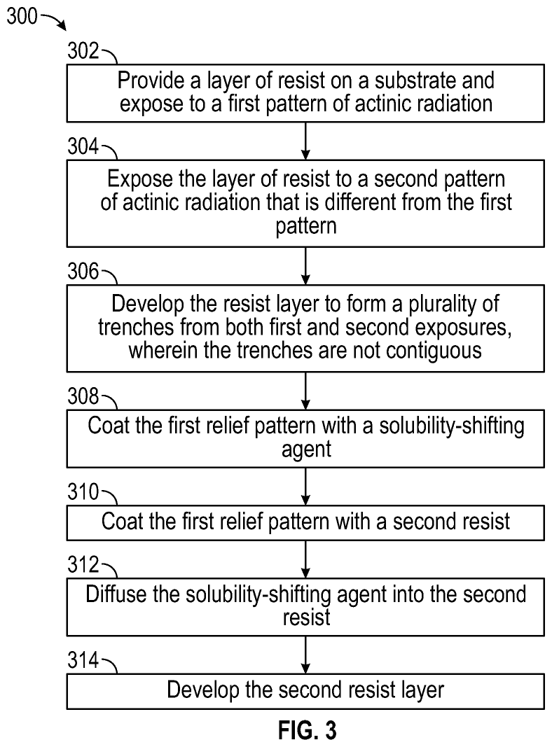

In one or more embodiments, an anti-spacer process as described in method 300, may be performed. A method 300 in accordance with the present disclosure is shown in, and discussed with reference to, FIG. 3. Initially, method 300 includes, at block 302, exposing a first region in a first resist layer to a first pattern of actinic radiation to form a first latent image. Block 304 includes exposing a second region in the first resist to a second pattern of actinic radiation to form a second latent image adjacent to the first latent image. Block 306 includes treating the first resist layer with a developer to form a first relief pattern comprising a plurality of features from both the first and second exposures, wherein the features are not contiguous but are separated by a first dimension. Block 308 includes coating the first relief pattern with a solubility shifting agent. The solubility shifting agent can be a solubilizing or hardening agent, based on the polarity of the first resist. In this embodiment, blocks 302, 304, 306, and 308 are similar to blocks 102, 104, 105, and 108 in method 100 (FIG. 1). However, in this embodiment, a second resist layer is coated on the solubility-shifting agent coated first relief pattern and the solubility-shifting agent diffuses out to the second photoresist. In one or more embodiments, diffusion of the solubility-shifting agent into the second resist is achieved by performing a bake. The baking process is similar to block 110 of method 100.

Block 310 includes coating the first relief pattern with a second resist. Block 312 includes diffusing the solubility-shifting agent into the second resist. Block 314 includes developing the second resist again. The second develop removes the solubility-shifted region at the sidewalls of the resist and results a first relief pattern of modified regions and a second pattern and a contiguous trench that wraps around the modified regions. This embodiment may wrap a trench around two existing features separated by a gap. The second resist defines the outer edges of the trench.

Method 300 represents one possible embodiment and is not intended to limit the scope of the present invention. As will be appreciated by one of ordinary skill in the art, the present invention may encompass various alternative methods, such as, for example, methods in which the solubility-shifting agent is diffused into and changes solubility of a region of the first resist rather than the second resist. In such alternate embodiments, the components and techniques used in the methods may be as previously described with reference to method 300.

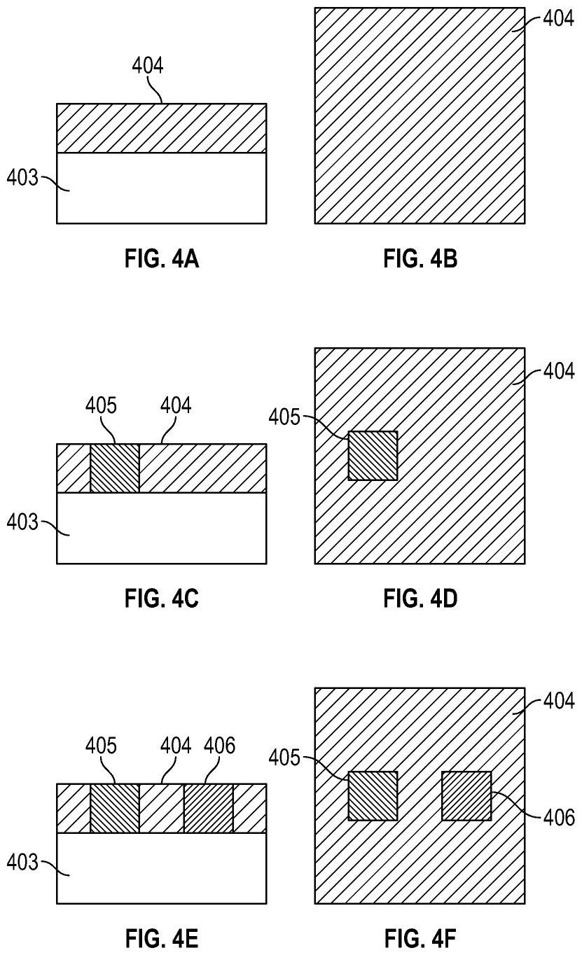

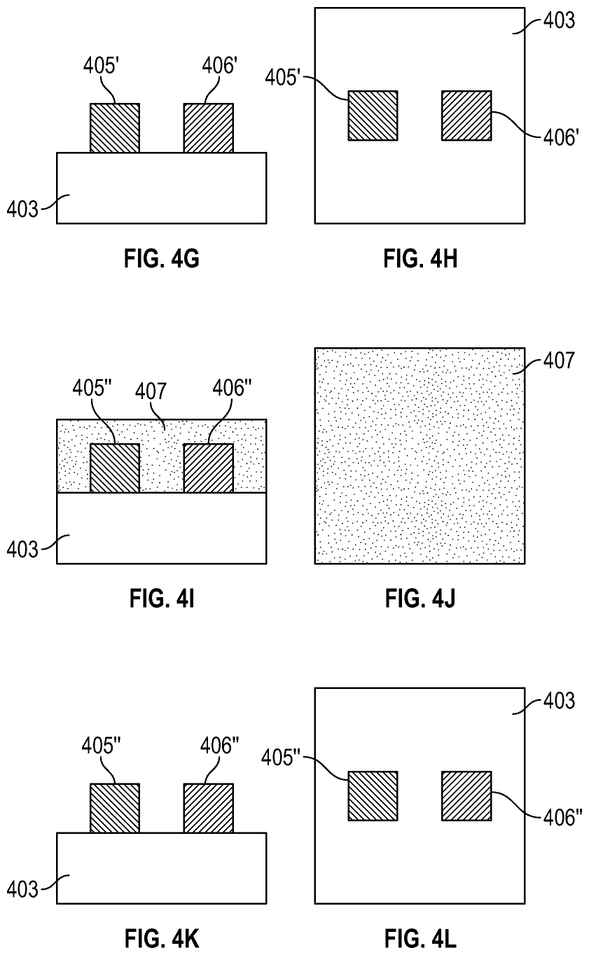

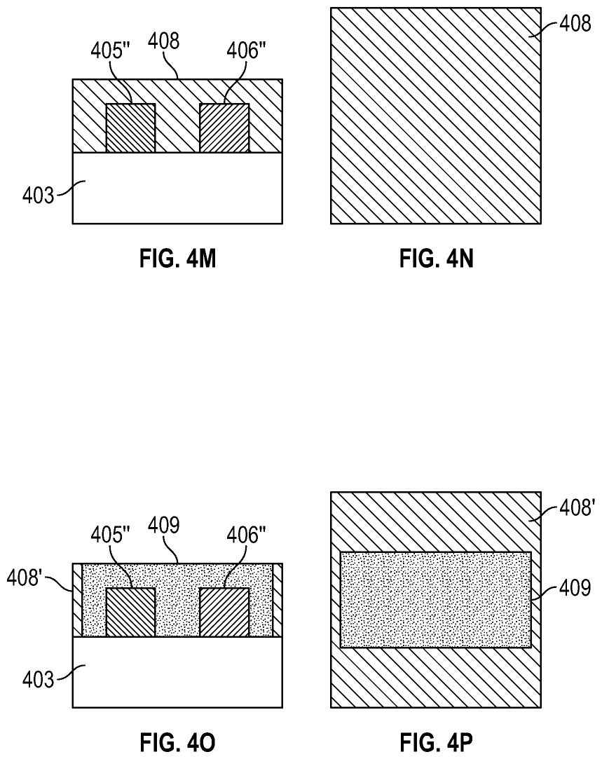

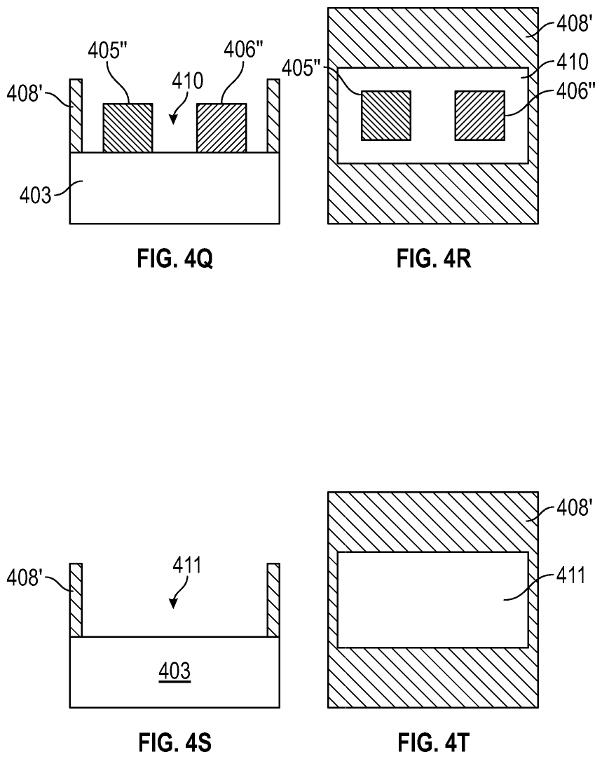

In one or more embodiments, the solubility-shifting agent is diffused into the first resist. In such embodiments, a method may include initially forming a first relief pattern of a first resist and then coating the first resist with a solubility-shifting agent. At this point, the solubility-shifting agent may be diffused into the first resist a predetermined distance to provide a solubility-shifted region of the first resist. FIG. 4I shows a coated substrate including a first resist 405 that has a solubility-shifted region 405′. While diffusion of the solubility-shifting agent may occur at a different point in such method and into a different component, diffusion of the solubility-shifting agent may be carried out as described above in method 300. After the solubility-shifting agent is diffused into the first resist, the second resist may be deposited on the substrate. FIG. 4M shows a first resist including a solubility-shifted region 405′ on a substrate coated with a second resist 408. Then, the substrate may be developed as described with reference to method 300, where the solubility-shifted region of the first resist is soluble in the specific developer.

Schematic depictions of a coated substrate at various points during the method described above are shown in FIG. 4. FIGS. 4A, 4C, 4E, 4G, 2I, 2K, 4M, 4O, 4Q, and 4S show cross-sectional schematic illustrations of coated substrates. FIGS. 4B, 4D, 4F, 4H, 4J, 4L, 4N, 4P, 4R, and 4T show corresponding top view schematic illustrations of coated substrates.

FIGS. 4A-B show a substrate 403 coated with first resist 404. FIGS. 4C-D show a substrate 403 including a first latent image 405 formed in resist 404. In FIGS. 4E-F, a second latent image 406 is formed in resist 404. FIGS. 4G-H show a coated substrate 403 after developing the first latent image 405 and second latent image 406 formed in resist 404 to form the first relief pattern of features 405′ and 406′. FIGS. 4I-J show a substrate 404 including a first relief pattern of features 405′ and 406′ coated with a solubility-shifting agent 407. FIGS. 4K-L show a substrate 403 including a first relief pattern of where the solubility-shifting agent has been diffused into the first resist to form first modified regions 405″ and 406″. In one or more embodiments, the solubility-shifting agent may not diffuse into the first resist. FIGS. 4M-N show a substrate 403 including a first relief pattern of first modified regions 405″ and 406″ containing the solubility-shifting agent that has been coated with a second resist 408. FIGS. 4O-P show a substrate 403 including a first relief pattern of first modified regions 405″ and 406″ and coated with a second resist 408 where the solubility-shifting agent has been diffused into the second resist to form solubility-shifted regions 409. Finally, FIGS. 4Q-R show a coated substrate 403 after final development, with a first relief pattern of first modified regions 405″ and 406″, a second relief pattern of a second modified region 408′, and trenches 410 between first modified regions 405′ and 406′ and between first modified region 405′ or 406′ and second modified region 408′.

Similar to block 102 in method 100, at block 302 of method 300, a first resist layer is provided. FIGS. 4A-B show an example of a first resist layer 404 on a substrate 403. Also, at block 302 of method 300, the first resist may be exposed to a first pattern of actinic radiation resulting in a first latent image 405 as shown in FIGS. 4C-D.

Next, at block 304 of method 300 like block 104 of method 100, the first resist 404 may be exposed to a second pattern of actinic radiation resulting in a second latent image 406 as shown in FIGS. 4E-F. The embodiment shown in FIGS. 4E-4H depict a positive tone resist. In one or more embodiments, a negative tone resist may be used. After the actinic radiation is applied, the unexposed portions of the resist may have a different solubility than the exposed portions of the resist.

At block 306 of method 300, the first resist may be rinsed with a first resist developer. Rinsing with the first resist developer will dissolve either the unexposed portion or the exposed portion. As shown in FIGS. 4G-H, the unexposed portion is rinsed away leaving a first relief pattern of features 405′ and 406′.

At block 308 of method 300, the first relief pattern is coated with a solubility-shifting agent. The solubility-shifting agent 407 is shown as a coating over the first relief pattern in FIGS. 4I-J. The solubility-shifting agent 407 may diffuse into the first resist to form first modified regions 405′ and 406′ or may not diffuse into the first resist. As shown in FIGS. 4K-L, the residual solubility-shifting agent may be removed to form a substrate 403 including a first relief pattern of first modified regions 405′ and 406′.

At block 312 of method 300, first relief pattern of first modified regions 405′ and 406′ may be coated with a second resist 408 as shown in FIGS. 4M-N. The second resist may be deposited on the substrate such that it fills gaps of the first relief pattern and is in contact with the first relief pattern or the solubility-shifting agent. In one or more embodiments, the second resist completely covers the substrate, the first relief pattern, and the solubility-shifting agent. The second resist may be deposited on the substrate according to any suitable method known in the art such as, for example, spin-on deposition or vapor-phase treatment.

In one or more embodiments, the second resist includes a polymer. Suitable polymers may be as previously described with respect to the polymer defined as the matrix polymer. In particular embodiments, suitable polymers may be made from monomers including p-hydroxystryene, styrene, t-butyl acrylate, and combinations thereof. In particular embodiments, the polymer is made from all three of p-hydroxystyrene, styrene, and t-butylacrylate. Such polymer may be prepared from a polymerization reaction including from about 50 to about 80% p-hydroxystyrene, from about 10 to about 30% styrene, and from about 10 to about 30% t-butylacrylate. For example, a polymerization reaction to produce a polymer included in the second resist may include p-hdroxystyrene in an amount ranging from a lower limit of one of 50, 55, 60, and 65% to an upper limit of one of 65, 70, 75, and 80%, where any lower limit may be paired with any mathematically compatible upper limit, and styrene and t-butyl acrylate in individual amounts ranging from a lower limit of one of 10, 12, 14, 16, 18, and 20% to an upper limit of one of 20, 22, 24, 26, 28, and 30%, where any lower limit may be paired with any mathematically compatible upper limit.

The polymer included in the second resist may have a weight average molecular weight (Mw) ranging from about 1 to about 100 kg/mol. For example, in one or more embodiments, the second resist may include a polymer having a Mw ranging from a lower limit of one of 1, 2, 5, 10, 15, 20, and 25 kg/mol to an upper limit of one of 25, 50, 75, 80, 90, and 100 kg/mol, where any lower limit may be paired with any mathematically compatible upper limit. A polymer having such Mw may exhibit desired solubility characteristics, such as, in particular, the dissolution rate.

In one or more embodiments, the second resist includes a photoacid generator. The photoacid generator may be as previously described with respect to the photoacid generator included in the first resist.

In one or more embodiments, the second resist includes a solvent. The solvent may be as previously described with respect to the solvent included in the solubility-shifting agent. In particular embodiments, the solvent in the second resist is the same as the solvent in the solubility-shifting agent.

The second resist may include additives having various purposes, depending on the particular chemistry being used. In one or more embodiments, a quencher is included in the second resist. A quencher may be included in the second resist to help control the diffusion of the active material in the solubility-shifting agent. Suitable quenchers include any of the bases previously listed with reference to the solubility-shifting material.

The second resist may be a PTD or NTD resist. Both PTD and NTD rests may include a polymer and a solvent as described above. In embodiments in which the second resist is an NTD resist, it may also include an acid or acid generator. The acid or acid generator is as previously described with reference to the solubility-shifting material.

At block 312 of method 300 the solubility-shifting agent is diffused into the second resist. In one or more embodiments, diffusion of the solubility-shifting agent into the second resist is achieved by performing a bake. The bake may be carried out with a hotplate or oven. The temperature and time of the bake may depend on the identity of the second resist, and the desired amount of diffusion of the solubility-shifting agent into the second resist. Suitable conditions for the bake may include a temperature ranging from 50 to 160° C., and a time ranging from about 30 to 90 seconds. In one or more embodiments, after the bake a solubility-shifted region may be present around the edges of the second resist. The amount of diffusion of the solubility-shifting agent may correspond to the thickness of the solubility-shifted region. In one or more embodiments, the solubility-shifted region extends into the second resist such that it has a thickness of about 5 to about 60 nm. For example, the thickness of the solubility-shifted region may range from a lower limit of one of 5, 10, 15, 20, and 25 nm to an upper limit of one of 40, 45, 50, 55, and 60 nm, where any lower limit may be paired with any mathematically compatible upper limit. In one or more embodiments, the thickness of the solubility-shifted region may correspond to the desired width of the line that is to be cut into the substrate.

A coated substrate including a solubility-shifted region is shown in FIGS. 4O-P. As shown in FIG. 40, the coated substrate includes a substrate layer 403. The substrate is as previously described. The first relief pattern of first modified regions of the first resist 405″ and 406″ coated with the solubility shifting agent is on top of the substrate 403. A solubility-shifted region 409 of the second resist is shown bordering the first relief pattern. A new pattern of second modified region of the second resist 408′ surrounds the solubility-shifted region 409.

The solubility-shifted region may have a different solubility than the region of the second resist that was unexposed to the solubility-shifting agent. As such, the solubility-shifted region and the unexposed region of the second resist may be soluble in different resist developers.

At block 314 of method 300, the deposited layer of the second resist may be developed using a specific developer such that the solubility-shifted region is removed as shown in FIGS. 4Q-R. Accordingly, dissolution of the solubility-shifted region may result in the formation of a recessed feature 410 between the first relief pattern of first modified regions 405″ and 406″ and the second modified regions of second resist 408′ in which the substrate 403 is exposed. In this embodiment, the solubility-shifting agent and the second modified region of second resist may be removed by the developer.

In yet another embodiment, the solubility-shifting agent changes the solubility of both the first and the second resist layer. In one or more embodiments, diffusion of the solubility-shifting agent into the first and second resist is achieved by performing a bake. The baking process is similar to the baking process described above. FIGS. 4S-4T show a coated substrate 403 after final development with features 408′ where all 405″ and 406″ are dissolved and one trench 411 is remaining on the substrate between the second modified region 408′.

The deposited layer of the second resist may be developed using a specific developer such that both the solubility-shifted region of the second resist and the first relief pattern of first modified regions 405″ and 406″ are removed as shown in FIGS. S-T. Accordingly, dissolution of the solubility-shifted regions may result in the formation of a recessed feature 411 within the second resist 408′ in which the substrate 403 is exposed as shown in FIGS. 4S-4T.

In one or more embodiments the specific developer may depend on the tone of the first resist. For example, if the first resist is a positive tone developed resist, the specific developer may be a base such as tetramethylammonium hydroxide. On the other hand, if the first resist is a negative tone developed resist, the specific developer may be a nonpolar organic solvent, such as n-butyl acetate or 2-heptanone.

In one or more embodiments, methods herein improve overlay for die stitching, enabling critical optoelectronic and semiconductor devices without sacrificing critical performance capabilities. The methods include using chemical treatments to improve feature registration, applying this to layer-in-layer stitching use cases with multiple exposure enhancement. Such cases enable very large dies to be fabricated, even dies up to a size of a wafer, while maintaining density and performance.

In one or more embodiments, methods herein include selective attachment processing, which improves resist formation at the boundary between stitched regions. This substantially reduces the design and overlay burden for stitched features, and eliminates some errors. Currently, state-of-the-art die stitching is to match ends, or use large “catch” areas for stitching. But these enlarged catch areas reduce density and valuable space for transistors. With this method, stitching can be done without error at sub nanometer precision and at full density.

What is claimed:

1. A method of patterning a substrate comprising:
providing a resist layer on the substrate;
exposing the resist layer to a first pattern of actinic radiation to form a first latent image in the resist layer;
exposing the resist layer to a second pattern of actinic radiation to form a second latent image in the resist layer, wherein the first latent image and the second latent image are adjacent;
developing the resist layer to form a relief pattern comprising a first set of trenches corresponding to the first pattern of actinic radiation and a second set of trenches corresponding to the second pattern of actinic radiation, wherein the first set of trenches and the second set of trenches are not contiguous;
coating the relief pattern with a solubility-shifting agent;
diffusing the solubility-shifting agent a predetermined distance into the resist layer to provide a solubility-shifted region of the resist layer, wherein the solubility-shifted region of the resist layer borders the first relief pattern;
developing the resist layer to stitch together the first set of trenches and the second set of trenches.

2. The method of claim 1, wherein the solubility-shifting agent comprises an acid-generator.

3. The method of claim 2, wherein the acid-generator is free of fluorine.

4. The method of claim 2, wherein the acid-generator is selected from the group consisting of pyridinium perfluorobutane sulfonate, 3-fluoropyridinium perfluorobutanesulfonate, 4-t-butylphenyltetramethylenesulfonium perfluoro-1-butanesulfonate, 4-t-butylphenyltetramethylenesulfonium 2-trifluoromethylbenzenesulfonate, 4-t-butylphenyltetramethylenesulfonium 4,4,5,5,6,6-hexafluorodihydro-4H-1,3,2-dithiazine 1,1,3,3-tetraoxide, triphenylsulfonium antiomate, and combinations thereof.

5. The method of claim 1, wherein the solubility-shifting agent comprises an acid.

6. The method of claim 5, where the acid is free of fluorine.

7. The method of claim 5, wherein the acid is selected from the group consisting of trifluoromethanesulfonic acid, perfluoro-1-butanesulfonic acid, p-toluenesulfonic acid, 4-dodecylbenzenesulfonic acid, 2,4-dinitrobenzenesulfonic acid, 2-trifluoromethylbenzenesulfonic acid, and combinations thereof.

8. The method of claim 1, wherein the solubility-shifting agent comprises a matrix polymer comprising monomers with ethylenically unsaturated polymerizable double bonds, including (meth)acrylate monomers; (meth)acrylic acids; styrene; hydroxystyrene; vinyl naphthalene; acenaphthylene; vinyl alcohol; vinyl chloride; vinyl pyrrolidone; vinyl pyridine; vinyl amine; vinyl acetal; maleic anhydride;
maleimides; norbornenes; and combinations thereof.

9. The method of claim 1, wherein the solubility-shifting agent comprises a matrix polymer comprising monomers comprising one or more functional groups chosen from hydroxy, carboxyl, sulfonic acid, sulfonamide, silanol, fluoroalcohol, anhydrates, lactones, esters, ethers, allylamine, pyrrolidones, and combinations thereof.

10. The method of claim 1, further comprising, directly after coating the first relief pattern with the solubility-shifting agent, diffusing the solubility-shifting agent into the first relief pattern.

11. The method of claim 1, wherein diffusing the solubility-shifting agent into the first relief pattern is achieved by performing a bake.

12. The method of claim 1, wherein the resist layer is a positive tone developed resist.

13. The method of claim 1, wherein the resist layer is a negative tone developed resist.

14. The method of claim 1, wherein the solubility-shifting agent comprises a solvent.

15. The method of claim 14, wherein the solvent is selected from the group consisting of methyl isobutyl carbinol (MIBC), decane, isoobutyl isobutyrate, isoamyl ether, and combinations thereof.

16. The method of claim 14, wherein the resist layer is insoluble in the solvent.

17. The method of claim 16, wherein the resist layer comprises a polymer made from monomers selected from the group consisting of styrene, p-hydroxystyrene, acrylate, methacrylate, norbornene, and combinations thereof.

18. The method of claim 1, wherein the resist layer is a positive tone developed resist and a specific developer is a base developer.

19. (canceled)

20. (canceled)

21. A method of patterning a substrate comprising:
providing a first resist layer on a substrate;
exposing the first resist layer to a first pattern of actinic radiation to form a first latent image;
exposing the first resist layer to a second pattern of actinic radiation
developing the first resist layer to form a relief pattern comprising a first set of trenches corresponding to the first pattern of actinic radiation and a second set of trenches corresponding to the second pattern of actinic radiation, wherein the first set of trenches and the second set of trenches are not contiguous;
coating the relief pattern with a solubility-shifting agent;
coating the relief pattern with a second resist layer;
diffusing the solubility-shifting agent a predetermined distance into the second resist layer to provide a solubility-shifted region of the second resist layer, wherein the solubility-shifted region of the second resist layer borders the first relief pattern;
developing the second resist layer to stitch together a plurality of trenches.

22. A method of patterning a substrate comprising:
providing a first resist layer on a substrate;
exposing the first resist layer to a first pattern of actinic radiation to form a first latent image;
exposing the first resist layer to a second pattern of actinic radiation developing the first resist layer to form a relief pattern comprising a first set of trenches corresponding to the first pattern of actinic radiation and a second set of trenches corresponding to the second pattern of actinic radiation, wherein the first set of trenches and the second set of trenches are not contiguous;
coating the relief pattern with a solubility-shifting agent;
coating the relief pattern with a second resist layer;
diffusing the solubility-shifting agent a predetermined distance into the first resist layer to provide a solubility-shifted region of the first resist layer, wherein the solubility-shifted region of the first resist layer borders the second resist layer;
developing the second resist layer to stitch together a plurality of trenches.

23.-43. (canceled)
